(19) United States
(12) Patent Application Publication
(10) Pub. No.: US 2016/0376696 A1
(43) Pub. Date: Dec. 29, 2016

(54) SPUTTERING TARGET

(71) Applicant: TDK CORPORATION, Tokyo (JP)

(72) Inventors: Kenichi KIUCHI, Tokyo (JP); Minoru IINO, Tokyo (JP); Yukio KAWAGUCHI, Tokyo (JP)

(73) Assignee: TDK CORPORATION, Tokyo (JP)

(21) Appl. No.: 15/196,896

(22) Filed: Jun. 29, 2016

(30) Foreign Application Priority Data
Jun. 29, 2015 (JP) 2015-130135

(51) Int. Cl. C23C 14/34; H01J 37/34

(52) U.S. Cl. CPC C23C 14/3414; H01J 37/3426

(57) ABSTRACT

A sputtering target containing a perovskite-type oxide as a principal component, wherein a crystal grain diameter of the perovskite-type oxide is from 11 to 15 μm, and wherein a flexural strength of 60 Mpa or more.

### TECHNICAL FIELD

The present invention relates to a sputtering target.

### BACKGROUND

Sputtering is a film forming method that is used widely in fields, which require high quality thin films, such as semiconductor elements, liquid crystal display devices, and optical media. Depending on the types of applied voltage, sputtering is broadly classified into direct current (DC) sputtering and radio frequency (RF) sputtering. From the standpoints that an inexpensive power source can be used, the rate of film formation is speedy, and that the increase in substrate temperature is small, the film formation through the DC sputtering occupies the main stream in the mass production processes of thin film products.

The DC sputtering requires a sputtering target itself to be conductive. Therefore, when thin films of dielectric materials such as perovskite-type oxides, which are used as thin film materials for a capacitor, are to be produced by sputtering, the film formation has been performed by the RF sputtering (Patent Literatures 1 and 2). It has also been suggested that a target comprising a conductive sintered material of barium titanate is used to carry out film formation in accordance with low frequency sputtering (Patent Literature 3).

### CITATION LIST

### Patent Literature

Patent Literature 1: Japanese Unexamined Patent Publication No. 2000-1773
Patent Literature 2: Japanese Patent No. 3129233
Patent Literature 3: Japanese Unexamined Patent Publication No. 2013-213257

### SUMMARY

Since the DC sputtering has the above-stated advantages, it is thus desired that the film formation be carried out by the DC sputtering even in producing a thin film of a perovskite-type oxide which is poor in conductivity. However, the sputtering target for forming a film of a dielectric material such as a perovskite-type oxide has low thermal conductivity. Hence, it has been found that when such sputtering target was used to carry out the DC sputtering, heat was confined within the surface of the sputtering target and the sputtering target was likely to fracture during the film formation. Therefore, the sputtering target needed to be thinned, and this would bring the problems that are associated with an increase in costs and a decrease in productivity.

The present invention has been made in consideration of the above-described objective problems and has an object of providing a sputtering target that hardly fractures during DC sputtering even if its thickness is made large.

(Sputtering Target)

The sputtering target of the present invention comprises a perovskite-type oxide as a principal component, wherein a crystal grain diameter of the perovskite-type oxide is from 11 to 15 μm and a flexural strength of 60 Mpa or more.

According to the present invention, there can be provided a sputtering target that hardly fractures during the DC sputtering even if its thickness is made large.

### BRIEF DESCRIPTION OF THE DRAWINGS

FIG. 1 is a metallurgical microscopic photograph of a section of a sputtering target obtained in Example 5.

### DETAILED DESCRIPTION

The sputtering target of the present embodiment comprises a perovskite-type oxide as a principal component, wherein the perovskite-type oxide has a crystal grain diameter of from 11 to 15 μm, and wherein a flexural strength of 60 Mpa or more. Such sputtering target hardly fractures during the DC sputtering even if its thickness is made large. The present inventors infer that this is because the thermal conductivity of the sputtering target according to the present embodiment is improved since it has a large crystal grain diameter and a small grain boundary.

The perovskite-type oxide is an oxide having a crystal structure of the perovskite and can be represented by general formula of ABO₃. As used herein, “A” and “B” represent an ion occupying A site (A ion) and an ion occupying B site (B ion), respectively. As “A ion,” there are mentioned Mg, Ca, Sr, Ba, and Pb. As “B ion,” there are mentioned Ti and Zr. A ion and B ion may be each one type of ion or two or more types of ions. The sputtering target comprises a perovskite-type oxide as the principal component. As used herein, the principal component means, for example, a level of 80 mol % or more and is preferably a level of 92 mol % or more relative to the whole sputtering target.

The sputtering target contains crystal grains and a grain boundary that exists between the crystal grains themselves. It is preferable that the crystal grain comprises a perovskite-type oxide as the principal component. It is also preferable that the grain boundary comprises the perovskite-type oxide as the principal component. The crystal grain diameter of the perovskite-type oxide is from 11 to 15 μm and preferably from 12 to 14 μm. The maximum grain diameter of the perovskite-type oxide is preferably from 13 to 20 μm. Note that the crystal grain diameter can, for example, be acquired from the average value of tangential diameters in a fixed direction in a cross sectional metallurgical microscopic photograph. Also, the maximum grain diameter of the perovskite-type oxide can, for example, be acquired from the maximum value of tangential diameters in a fixed direction in a cross sectional metallurgical microscopic photograph.

The sputtering target of the present embodiment may comprise additive(s) in addition to the perovskite-type oxide. Such additive is preferably an oxide or salt (e.g., a carbonate) of Group IIIB (scandium group), Group VB (vanadium group), Group VIB (chromium group), or Group VIIB (manganese group), from the viewpoint of improving the dielectric characteristics of a film that is formed using the sputtering target. The content of the additive is preferably from 0.01 to 3 mol % relative to the whole sputtering target.

The sputtering target of the present embodiment may contain unavoidable impurity particles in addition to the above-described components. Examples of the unavoidable impurity particles include particles of Na₂O, SiO₂, Al₂O₃, and Fe₂O₃, the respective particles of which can be tolerated up to about 1000 mass ppm.

The sputtering target has a flexural strength of 60 MPa or more, and preferably from 80 to 100 MPa. As used herein, the flexural strength refers to that which is measured in accordance with the three-point bending test as defined in JIS R-1601, for example.

Preferably, the sputtering target has a sintered density of from 80 to 99%. Note that the sintered density refers to the density of a sintered body relative to the theoretical density.

The sputtering target has preferably a resistivity of from 0.01 to 10 Ωcm, and more preferably from 0.01 to 0.7 Ωcm. Having such resistivity value, the sputtering target can preferably be used in the film formation with DC sputtering.

The sputtering target has preferably a thermal conductivity of from 3 to 12 W/mK, and more preferably from 8 to 12 W/mK. Having such thermal conductivity, the sputtering target hardly fractures even if its thickness is made large when it is used in the DC sputtering.

The shape and size of the sputtering target are not particularly limited and it can be made into a disk having a diameter of a level of from 127 to 300 mm, for example.

The thickness of the sputtering target can, for example, be set at from 7 to 10 mm. The sputtering target of the present embodiment can improve the cost reduction and the productivity of thin film products because it hardly fractures during the film formation through the DC sputtering even if it is shaped to such thickness.

Method for Manufacturing Sputtering Target

One example of the method for manufacturing a sputtering target according to the present embodiment will be described.

First, a material powder having the same composition as that of a desired sputtering target is prepared. The material powder contains a powder of a perovskite-type oxide as the principal component and contains a power(s) of the above-described additive(s) when necessary. The powder of the perovskite-type oxide has an average particle diameter of from 0.5 to 0.7 μm, and preferably from 0.5 to 0.6 μm. As used herein, the average particle diameter refers to, for example, a particle diameter of which the integrated volume percentage reaches 50% in a distribution curve of particle diameters as measured by laser diffraction. Also, the purity of the perovskite-type oxide power is preferably from 99 to 99.9% by mass. The purity of the optional additive powder is preferably from 99.9 to 99.99% by mass.

The method of obtaining the powder of the perovskite-type oxide is not particularly limited, and commercial ones may be used. Synthesized products from the solid state method, the oxalic acid method, the hydrothermal method, the sol-gel method, etc. are subjected to pulverization, sieving, or the like so that their average particle diameters may be in the above-described range, which may also be used.

In preparing the material powder, the perovskite-type oxide is admixed with a powder of an oxide or salt (e.g., a carbonate) of Group IIIB (scandium group), Group VB (vanadium group), Group VIB (chromium group), or Group VIIB (manganese group), where they are preferably admixed in a dry process. The admixing method is not particularly limited and is preferably conducted in a ball mill, for example.

Next, the obtained material powder is preferably shaped to obtain a shaped body. The shaping method is not particularly limited and there are, for example, mentioned dry shaping and a method of shaping with isostatic pressing. The isostatic pressing includes cold isostatic pressing (CIP method), warm isostatic pressing (WIP method), and others. The pressure during shaping the material powder is set, for example, such that the dry shaping is in the range of from 5 to 50 MPa and the isostatic pressing is in the range of from 100 to 500 MPa. It is preferable that the shaped body does not contain any binder. When the shaped body does not contain any binder, it will be easy to bring the crystal grain diameter of the perovskite-type oxide in a sintered body within the range of from 11 to 15 μm because the shaped body is not susceptible to the grain growth inhibition by residual carbon in sintering to be mentioned later. Here, as the binder, there are mentioned ones that are commonly used to shape raw material powders in methods for producing sintered bodies of oxides. Specifically, polyvinyl alcohol (PVA) is mentioned.

Next, the material powder is sintered to obtain a sintered body. Sintering is carried out at a temperature of from 800 to 1400° C., and preferably, at from 900 to 1300° C. At sintering, it is preferable that the sintering is carried out without the use of a method, such as hot pressing, where pressure that is not isotropic is applied. In the method for manufacturing a sputtering target according the present embodiment, the sintering is carried out by applying isotropic pressure to the raw material powder, or alternatively, by applying no pressure. Therefore, the grain growth is accelerated during sintering and the sputtering target to be obtained after the sintering is such that the crystal grain diameter of the perovskite-type oxide can easily be set at from 11 to 15 μm and the flexural strength of the sputtering target can easily be set at 60 MPa or more. The sputtering target obtained by such method hardly fractures even when used in the DC sputtering. The sintering time employed in the sintering is preferably from 10 to 20 hours. The atmosphere at the sintering is not particularly limited and may be an inert atmosphere, air, or vacuum atmosphere.

The obtained sintered body is processed, such as by cutting into a predetermined size, to complete the sputtering target. The sputtering target of the present embodiment has high thermal conductivity and hardly fractures during sputtering; therefore, it can be used for either of the RF sputtering and the DC sputtering.

Method for Manufacturing Thin Film

One example of the method for manufacturing a thin film by using the sputtering target according to the present embodiment will be described hereinbelow.

The sputtering target is first prepared. A cooling plate made of copper is bonded to the principle plane of the sputtering target with In or the like.

The sputtering target attached with the cooling plate is mounted on a DC sputtering device, and a film is formed on a substrate by the DC sputtering under an atmosphere containing oxygen. The material of the substrate is not particularly limited and can be selected appropriately, depending on its use. The examples, however, include a Si substrate and substrates of metals or coated with the metals, such as PT, Pd, and Ni. A rare gas such as Ar can be used as a sputtering gas.

The film formation as described above allows dielectric thin films to be obtained. The uses of the dielectric thin film include electronic components such as a capacitor and a piezoelectric element.

### EXAMPLES

Material powders having the compositions shown in Table 1 were prepared. Each of the material powders has a purity of 99.9% by mass and an average particle diameter of 0.5 μm. The prepared material powders were subjected to dry shaping at 30 MPa. The obtained shaped bodies were sintered with the sintering times and temperatures shown in Table 1 under vacuum atmosphere (6 Pa) without the application of pressure. The obtained sintered bodies were cut out into sizes of 200 mm φ and a thickness of 10 mm with a surface grinding machine and a cylindrical grinding machine to obtain the sputtering targets of Examples 1 to 9 and Comparative Examples 1 to 12.

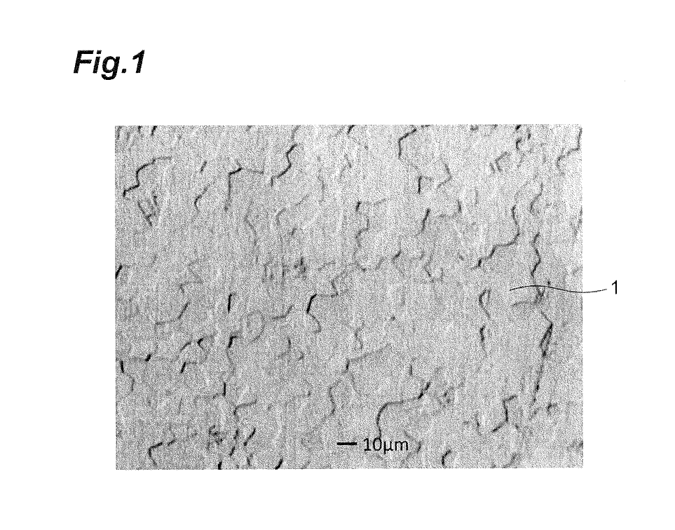

FIG. 1 shows a metallurgical microscopic photograph of the sputtering target of Example 5. As FIG. 1 shows, crystal grain 1 of the perovskite-type oxide having a crystal grain diameter of 13 μm was observed.

### Comparative Example 13

The material powder having the composition shown in Table 1 was prepared. The material powder of Comparative Example 13 had a purity of 99.9% by mass and an average particle diameter of 13 μm. The prepared material powder was subjected to dry shaping. The obtained shaped body was subjected to hot press sintering with the sintering time and temperature shown in Table 1 at a load of 19.6 MPa (200 kg/cm²) under vacuum atmosphere (6 MPa), whereby a sintered body was obtained. The obtained sintered body was cut out into a size of 200 mmφ and a thickness of 10 mm with the surface grinding machine and the cylindrical grinding machine to obtain the sputtering target.

Evaluation of Sputtering Targets

### (1) Resistivity

As for each of the sputtering targets of Examples 1 to 9 and Comparative Examples 1 to 13, the resistivity was measured using a resistivity measuring device in accordance with the four probe method as defined in JIS K-7194. Results are shown in Table 1.

### (2) Thermal Conductivity

As for each of the sputtering targets of Examples 1 to 9 and Comparative Examples 1 to 13, the thermal conductivity was measured using a thermal constant measuring device. Results are shown in Table 1.

### (3) Flexural Strength

As for each of the sputtering targets of Examples 1 to 9 and Comparative Examples 1 to 13, the flexural strength was measured using a strength measuring device in accordance with the three-point bending test as defined in JIS R-1601. The flexural strengths are shown in Table 1.

### (4) Stability in DC Sputter

As for the sputtering targets of Examples 1 to 9 and Comparative Examples 1 to 13, each was bonded to a cooling plate, which was made of a Cu alloy, by using indium. This sputtering target was mounted on the sputtering device and the DC sputtering was carried out with the application of a voltage of 3 W/cm² under an Ar atmosphere. The rate of film formation was 6.5 nm/min. After the DC sputtering, the sputtering target was taken out and viewed with the naked eyes under a fluorescent light; one with cracks or chips was determined to be “fracture.” Results are shown in Table 1. When cracks or chips are generated in the sputtering target during the DC sputtering, the presence or absence of the “fracture” can be ascertained to a certain degree even during the sputtering since the discharge voltage and current change suddenly during the sputtering.

TABLE 1

| | | Sintering | Sintering | Crystal Grain | Thermal | | Target | DC | Flexural |
|---|---|---|---|---|---|---|---|---|---|
| | | Time | Temperature | Diameter | Conductivity | Resistivity | Thickness | Sputter | Strength |
| | Composition | (h) | (° C.) | (μm) | (W/mK) | (Ωcm) | (mm) | Stability | (Mpa) |
| Example 1 | BaTiO₃ | 20 | 1300 | 15 | 10 | 0.02 | 10 | good | 94 |
| Example 2 | BaTiO₃ | 15 | 1300 | 13 | 8 | 0.03 | 10 | good | 98 |
| Example 3 | BaTiO₃ | 10 | 1300 | 11 | 3 | 0.05 | 10 | good | 99 |
| Example 4 | Pb(Zr_{0.5}Ti_{0.5})O₃ | 20 | 1300 | 15 | 10 | 0.03 | 10 | good | 87 |
| Example 5 | Pb(Zr_{0.5}Ti_{0.5})O₃ | 15 | 1300 | 13 | 8 | 0.04 | 10 | good | 90 |
| Example 6 | Pb(Zr_{0.5}Ti_{0.5})O₃ | 10 | 1300 | 11 | 3 | 0.06 | 10 | good | 92 |
| Example 7 | (Ba_{0.5}Sr_{0.5})TiO₃ | 20 | 1300 | 15 | 11 | 0.02 | 10 | good | 65 |
| Example 8 | (Ba_{0.5}Sr_{0.5})TiO₃ | 15 | 1300 | 13 | 8 | 0.03 | 10 | good | 74 |
| Example 9 | (Ba_{0.5}Sr_{0.5})TiO₃ | 10 | 1300 | 11 | 4 | 0.05 | 10 | good | 78 |
| Comparative Example 1 | BaTiO₃ | 2 | 1300 | 6 | 2 | 1 | 10 | fracture | 41 |
| Comparative Example 2 | BaTiO₃ | 2 | 1300 | 5 | 2 | 8 | 10 | fracture | 43 |
| Comparative Example 3 | BaTiO₃ | 2 | 1300 | 1 | 2 | 12 | 10 | fracture | 43 |
| Comparative Example 4 | BaTiO₃ | 30 | 1300 | 20 | 3 | 1 | 10 | fracture | 37 |
| Comparative Example 5 | Pb(Zr_{0.5}Ti_{0.5})O₃ | 2 | 1300 | 6 | 2 | 2 | 10 | fracture | 38 |
| Comparative Example 6 | Pb(Zr_{0.5}Ti_{0.5})O₃ | 2 | 1300 | 5 | 2 | 8 | 10 | fracture | 38 |
| Comparative Example 7 | Pb(Zr_{0.5}Ti_{0.5})O₃ | 2 | 1300 | 1 | 2 | 12 | 10 | fracture | 35 |
| Comparative Example 8 | Pb(Zr_{0.5}Ti_{0.5})O₃ | 30 | 1300 | 20 | 3 | 1 | 10 | fracture | 34 |
| Comparative Example 9 | (Ba_{0.5}Sr_{0.5})TiO₃ | 2 | 1300 | 6 | 2 | 2 | 10 | fracture | 29 |
| Comparative Example 10 | (Ba_{0.5}Sr_{0.5})TiO₃ | 2 | 1300 | 5 | 2 | 7 | 10 | fracture | 30 |
| Comparative Example 11 | (Ba_{0.5}Sr_{0.5})TiO₃ | 2 | 1300 | 1 | 2 | 12 | 10 | fracture | 30 |
| Comparative Example 12 | (Ba_{0.5}Sr_{0.5})TiO₃ | 30 | 1300 | 20 | 4 | 0.8 | 10 | fracture | 27 |
| Comparative Example 13 | (Ba_{0.5}Sr_{0.5})TiO₃ | 2 | 1300 | 13 | 2 | 2 | 10 | fracture | 25 |

### REFERENCE SIGNS LIST

1 crystal grain

What is claimed is:

1. A sputtering target comprising a perovskite-type oxide as a principal component, wherein a crystal grain diameter of the perovskite-type oxide is from 11 to 15 μm and, wherein a flexural strength is 60 Mpa or more.
